(19) United States
(12) Patent Application Publication
(10) Pub. No.: US 2011/0187389 A1
(43) Pub. Date: Aug. 4, 2011

(54) CAPACITANCE MEASURING CIRCUIT FOR TOUCH SENSOR

(75) Inventors: Sang Hyun Han, Gyeonggi-do (KR); Do Yeun Na, Seoul (KR); In Jun Choi, Gyeonggi-do (KR)

(73) Assignee: POINTCHIPS CO., LTD., Seoul (KR)

(21) Appl. No.: 12/679,046

(22) PCT Filed: Sep. 10, 2008
(86) PCT No.: PCT/KR2008/005342

§ 371 Date: Mar. 19, 2010

(30) Foreign Application Priority Data
Sep. 19, 2007 (KR) 10-2007-0095453

(51) Int. Cl. G01R 27/26

(52) U.S. Cl. 324/679

(57) ABSTRACT

Disclosed herein is a capacitance measuring circuit for a touch sensor. The capacitance measuring circuit includes a reference voltage generation unit for generating a first reference voltage and a second reference voltage, a MUX unit for selecting one from among electrode voltages, a voltage comparator for comparing a voltage generated by the reference voltage generation unit with the electrode voltage, a charging/discharging circuit unit for performing charging of the input electrode voltage from the first reference voltage to the second reference voltage or performing discharging of the input electrode voltage from the second reference voltage to the first reference voltage, a timer unit for receiving an external control signal, measuring charging time and discharging time of the charging/discharging circuit unit, measuring entire charging time and entire discharging time, and outputting corresponding output signals, and a control unit for receiving an output signal of the voltage comparator and the external control signal, and controlling the charging/discharging circuit unit and the timer unit.

### TECHNICAL FIELD

The present invention relates, in general, to a capacitance measuring circuit for a touch sensor, and, more particularly, to a capacitance measuring circuit for a touch sensor, which can measure the capacitance of a relevant electrode within a short period of time in such a manner that time measurement is performed by applying a specific constant current during both charging and discharging.

### BACKGROUND ART

The capacitance of an electrode PAD is determined through contact with a capacitor, which is an electrical element connected to the electrode PAD, its equivalent material, or a human body. In the case of a human body, it can be seen that, if a finger or a specific portion of the human body is directly brought into contact with the electrode PAD or if it is not directly brought into contact with the electrode PAD but only approaches the electrode PAD at an unspecified distance, a minute capacitance component is formed between the electrode PAD and the human body.

Furthermore, capacitance varies with variation in the distance between a portion of an approaching human body and the electrode. As a result of measurements, it is known that the capacitance increases as the distance between the electrode and the human body decreases, but is decreases as the distance between the electrode and the human body increases.

As described above, the distance between an electrode and a human body can be determined at a certain level by measuring the amount of variation in capacitance occurring depending on variations in the distance between the electrode and the human body. The value of specific critical capacitance is set using the results of the determination. If a capacitance component measured from the electrode is greater than a critical value, it is determined that a switch has been touched. If not, it is determined that the switch has not been touched.

The critical value is generally determined by experimentally calculating an initially measured value, which is measured when a touch sensor is powered on and is not touched, and a varying value, which varies depending on the surrounding environment, and then adding or subtracting the varying value to or from the initially measured value.

One of the products implemented using semiconductors using this method is a touch sensor IC. Such touch sensor ICs, instead of mechanical switches that had been used in various existing electronic products, have already been applied to numerous electronic products such as mobile phones, TVs, washing machines, air conditioners, and microwave ovens.

However, in such a touch sensor IC, the capacitance formed between an electrode PAD and a human body is only in a range of about several pF to about several tens of pF. Accordingly, in a prior art method of calculating such capacitance, as shown in FIGS. 1 and 2, the electrode PAD was fully discharged to a ground GND using an electrical switch SW, and then the time it takes to charge the electrode PAD with the capacitor component Cpad of capacitance, which is generated by an electrode PAD and a human body from a constant current source connected to a power source VDD, up to a reference voltage Vref was measured using a timer using a high-speed count clock, and the value of the capacitance was measured based on the value measured by the timer.

Here, a comparator COMP functions to compare a reference voltage Vref with the voltage VPAD of the electrode PAD, which varies depending on charging with the capacitor (Cpad) component formed in the electrode PAD. In a period in which a resulting signal OUT is high, the signal OUT is used as a signal for controlling a switch used to discharge the electrode PAD. In a period in which the signal OUT is Low, the signal OUT is used as a control signal for the timer in which the high-speed count clock measures the time of a period ‘tchar’.

In the prior art technology, due to the limitations of the high-speed count clock used to measure capacitance, discharging is completed within a relatively short period of time such as period ‘tdis’, and a current source that supplies very low current is used in order to obtain a sufficient timer value during charging. Here, the value of current supplied from the current source is generally in a range of about several hundreds of pA to about several uA. The reason why the characteristic of charging voltage increases linearly in period ‘tchar,’ as shown in FIG. 2, is that charging is performed using a constant current source.

In this case, in general, since the capacitance obtained between a human's finger and an electrode is generally only in a range of about several pF to several tens of pF, it is advantageous in that, if the value of charging current is reduced, a longer charging time is taken, and thus more timer values can be measured. However, if the current used for charging is excessively low, the influence caused by an external noise signal and parasitic current within a touch sensor semiconductor is increased, and thus there is a tendency for variation in the time it takes to perform charging to be increased or decreased by a noise component. Accordingly, there are many problems in measuring the time it takes to measure capacitance efficiently.

FIGS. 3 and 4 show another capacitance measuring circuit for a touch sensor. As shown in FIGS. 3 and 4, after an electrode PAD had been fully charged to VDD using an electrical switch SW, the time it takes to discharge the capacitor component Cpad of capacitance, which is generated by the electrode PAD and the human body through a resistor R connected to a ground GND, to a reference voltage Vref was measured using a timer using a high-speed count clock, and the value of the capacitance was measured based on a value measured by the timer.

A signal ‘ctl’, that is, a signal used to perform the charging or discharging of a capacitance component of the electrode, is a control signal that turns on/off the electrical switch. When the signal ‘ctl’ is high, the switch is turned on, so that the charging of the capacitance component of the electrode is performed at high speed within a relatively short period of time. When the switch is turned off, the electric charges stored in the capacitor of the electrode are discharged through the resistor R.

Here, a comparator COMP functions to compare the reference voltage Vref with a voltage Vpad, which varies depending on the discharging of the electrode. The time during which a signal ‘cnten’, which is output by performing a logical AND operation on an OUT signal (that is, the result of the comparison) and a signal ‘ctlb’ (that is, the inverse signal of ‘ctl’), is high, is measured using the timer, and the value of capacitance is measured using the time.

In this prior art, due to the limitation of the high-speed count clock used to measure capacitance, in the case of fast charging, charging is completed within a relatively very short period of time, such as a period ‘tcharg’, and, in the case of discharging, a resistor having a resistance value R of mega OHM or higher is connected so as to obtain a sufficient timer value. Here, in general, in the case where electric charges stored in the capacitor Cpad are discharged through the resistor R, a minute current ranging from about several hundreds of pA to about several uA is used as the discharging current.

As shown in FIG. 4, the reason why a discharging voltage characteristic decreases in the form of an exponential function in periods ‘tdis1’ and ‘tdis2’ is that, since a discharging path is formed via the resistor R, the discharging voltage characteristic has the slope of a discharging characteristic of a R-C circuit (that is, a general electrical circuit).

However, even in this prior art, the capacitance obtained between a human's finger and an electrode is generally only in the range of about several pF to several tens of pF. Accordingly, it is advantageous in that, if the value of discharging current is reduced, a longer charging time is taken, and thus more timer values can be measured. However, if the current used for charging is excessively low, the influence caused by an external noise signal and parasitic current within a touch sensor semiconductor is increased, and thus there is a tendency for variation in the time it takes to perform charging is increased or decreased by a noise component. As a result, there are many problems in measuring the time it takes to perform charging of capacitance efficiently.

In the case where the above-described prior art is implemented using semiconductor ICs, the charging or discharging current used to measure desired capacitance is only in the range of several hundreds of pA to several uA as described above. Accordingly, there have been many problems because the signal to noise ratio related to the influence of operating environment disturbing components, such as leakage current caused by parasitic resistance, which is parasitic on semiconductor elements implemented on a silicon wafer due to semiconductor characteristics, temperature, external moisture and electromagnetic wave (electric wave) components, could not be increased.

Furthermore, in order to obtain the timer value of stabilized capacitance, as shown in FIGS. 2 and 4, even in the case where the discharging and charging of the capacitance component of one electrode PAD has been performed, charging or discharging using minute current must be performed after a wait of a time period, such as a period ‘tdis’ [FIG. 2] or ‘tcharg’ [FIG. 4], is performed so as to reduce the influence caused by variation in the external environment, so as to obtain a desired specific timer value.

Furthermore, in order to prepare for the case where sufficient charging and discharging timer values are not obtained, the capacitance of the electrode is calculated through timer values that are measured by repeatedly performing a number of tcycles, so that the time taken for each electrode is long. Accordingly, in the case where a large number of the electrodes PAD is provided and a touch sensor for sequentially measuring the capacitance of the respective electrodes PAD is required, the response characteristic of each pin desired by a user cannot be obtained. As a result, there is a disadvantage in that, in the above case, several touch sensor ICs must be used.

### DISCLOSURE

### Technical Problem

Accordingly, the present invention has been made keeping in mind the above problems occurring in the prior art, and an object of the present invention is to provide an electrical circuit which can minimize the influence of an external environment occurring because the value of capacitance formed between a human body and an electrode is very low, and thus a current of only about several hundreds of pA to several uA is used to measure the charging or discharging time of a capacitance component formed in the electrode, which can minimize the influence of the leakage current characteristics of a silicon-based semiconductor itself, and which can maximize the signal to noise ratio, thereby being capable of measuring capacitance more stably.

Another object of the present invention is to provide a structure which can measure the capacitance of a relevant electrode within a shorter period of time in such a way that time measurement is performed by applying a predetermined constant current for both charging and discharging.

A further another object of the present invention is to sequentially supply constant current required for charging and discharging through a current source using a current mirror during charging and discharging, and to perform a function in which only the number of corresponding cycles is increased within a separate predetermined period but the same effect can be obtained in the measurement of capacitance, even though the current value of the corresponding current source is increased compared to that of the prior art, thereby significantly improving the signal to noise ratio and minimizing the influence caused by the external environment and the leakage current on a semiconductor silicon wafer.

### Technical Solution

In order to accomplish the above objects, the present invention provides a capacitance measuring circuit for a touch sensor, including a reference voltage generation unit for generating a first reference voltage and a second reference voltage; a MUX unit for selecting one from among electrode voltages input through a plurality of electrodes; a voltage comparator for comparing a voltage generated by the reference voltage generation unit with the electrode voltage input from an electrode; a charging/discharging circuit unit for performing charging of the input electrode voltage from the first reference voltage to the second reference voltage or performing discharging of the input electrode voltage from the second reference voltage to the first reference voltage; a timer unit for receiving an external control signal, measuring charging time and discharging time of the charging/discharging circuit unit, measuring entire charging time and entire discharging time, and outputting corresponding output signals; and a control unit for receiving an output signal of the voltage comparator and the external control signal and controlling the charging/discharging circuit unit and the timer unit.

The reference voltage generation unit may include three resistors connected in series, and provide the first reference voltage and the second reference voltage as linear voltages.

The voltage comparator may include includes a second comparator for comparing the first reference voltage provided by the reference voltage generation unit with the electrode voltage generated in the electrode; and a first comparator for comparing the second reference voltage provided by the reference voltage generation unit with an electrode voltage generated in the electrode.

The charging/discharging circuit unit includes a current source for increasing the electrode voltage to the second reference voltage; and a switch unit for selecting one from among charging and discharging of the electrode voltage.

The current source includes a resistor (R) having one terminal connected to a power source voltage (VCC) and a remaining terminal connected to a drain terminal of an NMOS transistor (n0); the NMOS transistor (n0) having a source terminal connected to a ground terminal and the drain terminal connected to the remaining terminal of the resistor (R); an NMOS transistor (n1) having a source terminal connected to the ground terminal and a drain terminal connected to a drain terminal of a PMOS transistor (p0); a PMOS transistor (n2) having a source terminal connected to the ground terminal and a drain terminal connected to the switch unit; the PMOS transistor (p0) having a source terminal connected to a power source voltage (VCC) and the drain terminal connected to the drain terminal of the NMOS transistor (n1); and a PMOS transistor (p1) having a source terminal connected to a power source voltage (VCC) and a drain terminal connected to the switch unit; wherein a gate terminal and drain terminal of the NMOS transistor (n0) and a gate terminal of the NMOS transistor (n1) are commonly connected to a gate terminal of the NMOS transistor (n2); and wherein the drain terminal and gate terminal of the PMOS transistor (p0) are commonly connected to a gate terminal of the PMOS transistor p1.

The switch unit includes a first switch for selecting the charging of the electrode; and a second switch for selecting the discharging of the electrode.

The switch unit includes a first switch comprising a first inverter having an input terminal connected to an output terminal of the second comparator, and a PMOS transistor (p2) having a source terminal connected to a drain terminal of an NMOS transistor (n3), a drain terminal connected to a source terminal of the NMOS transistor (n3) and a gate terminal connected to an output terminal of the first inverter, wherein the output terminal of the first inverter and a gate terminal of the NMOS transistor (n3) are commonly connected to each other, and the source terminal of the PMOS transistor (p2) and the drain terminal of the NMOS transistor (n3) are connected to the current source; and a second switch comprising a second inverter having an input terminal connected to an output terminal of the first comparator, and a PMOS transistor (p3) having a source terminal connected to a drain terminal of an NMOS transistor (n4), a drain terminal connected to a source terminal of the NMOS transistor (n4), and a gate terminal connected to an output terminal of the second inverter, wherein the output terminal of the first inverter and a gate terminal of the NMOS transistor (n4) are commonly connected to each other, and the source terminal of the PMOS transistor (p3) and the drain terminal of the NMOS transistor (n4) are connected to the current source.

Capacitance is measured through an accumulated difference between charging and discharging time for existing capacitance and charging and discharging time for varied capacitance by successively performing a charging and discharging cycle one or more times.

Additionally, the present invention provides a capacitance measuring circuit for a touch sensor, including a reference voltage generation unit for generating a first reference voltage and a second reference voltage; a voltage comparator for comparing an electrode voltage input from an electrode with voltage generated by the reference voltage generation unit; and a charging/discharging circuit unit for performing charging of the input electrode voltage from the first reference voltage to the second reference voltage or performing discharging of the input electrode voltage from the second reference voltage to the first reference voltage; wherein charging and discharging time and total charging and discharging time consumed through the charging/discharging circuit unit are measured, a charging and discharging cycle is performed two or more times, and capacitance is measured through an accumulated difference between charging and discharging time for existing capacitance and charging and discharging time for varied capacitance using corresponding charging and discharging time and total charging and discharging time.

### Advantageous Effects

The present invention constructed and operated as described above uses a method of repeating a process of obtaining the time it takes to perform charging and discharging at the same time using current significantly higher than charging and discharging current and measuring variation in corresponding capacitance by reading the time as timer values during a predetermined number of cycles regardless of charging and discharging current. As a result, there are advantages in that influence caused by the environments inside and outside a touch sensor can be minimized, and capacitance can be measured more accurately and stably even when a clock identical to that of the prior art is used.

### DESCRIPTION OF DRAWINGS

FIGS. 1 to 4 are diagrams showing the construction of a prior art touch sensor and related graphs;

FIG. 5 is a schematic diagram showing a capacitance measuring circuit for a touch sensor according to the present invention;

FIG. 6 is a detailed view of the capacitance measuring circuit for a touch sensor according to the present invention;

FIG. 7 is a detailed view of the charging/discharging circuit unit according to the present invention;

FIG. 8 is a detailed view of the switch unit of the charging/discharging circuit unit according to the present invention;

FIGS. 9 to 11 are graphs showing the charging and discharging cycles of the capacitance measuring circuit according to the present invention; and

FIG. 12 is a flowchart showing the sequence of the operation of the measurement circuit according to the present invention.

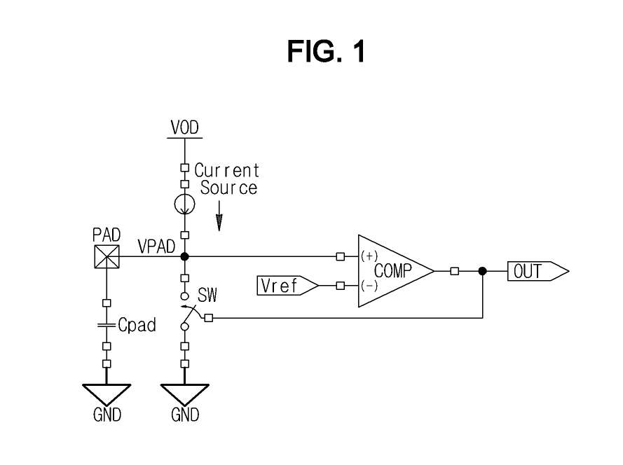

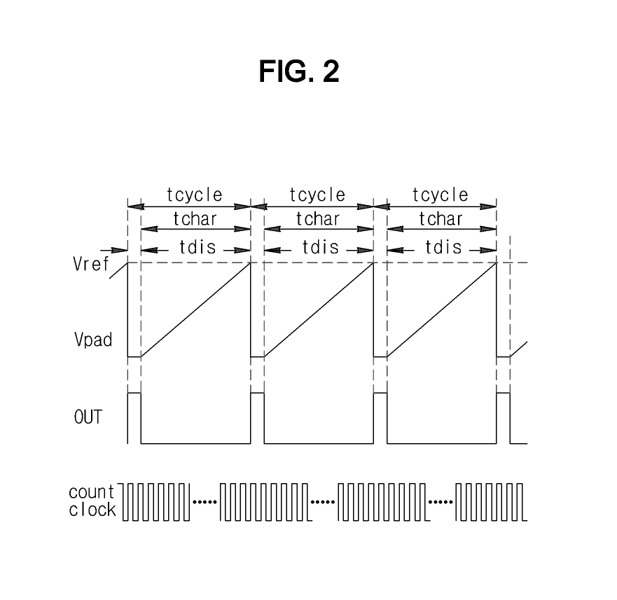

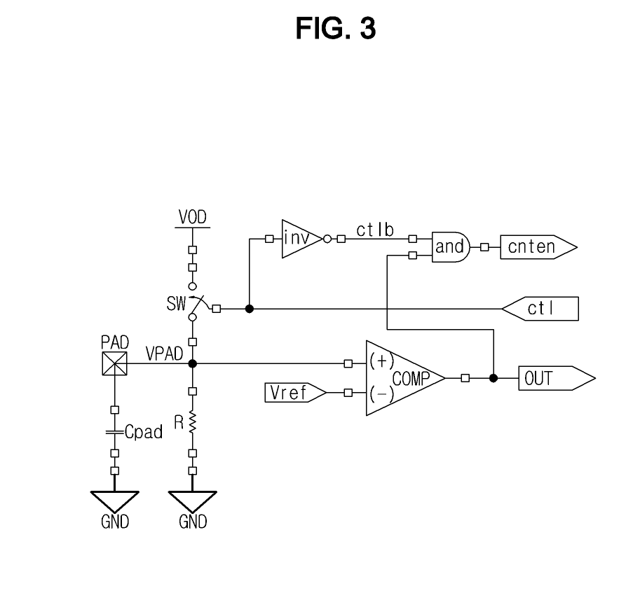

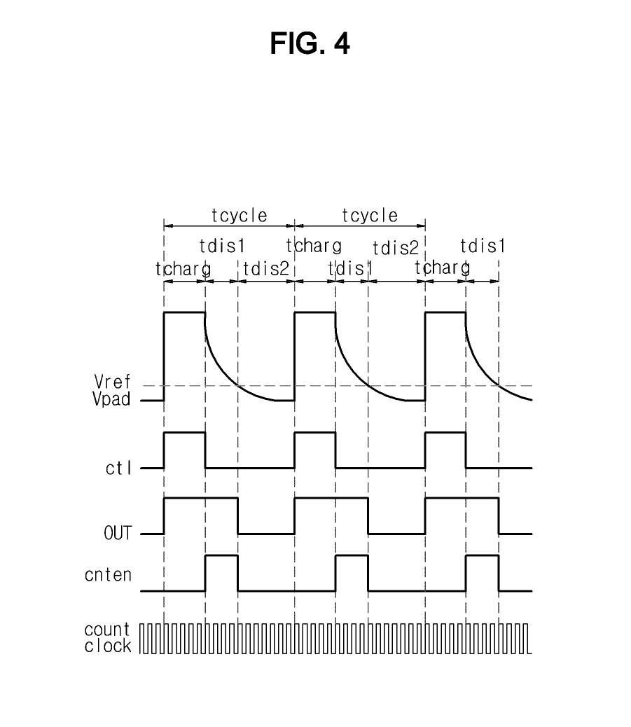

### MODE FOR INVENTION

An embodiment of a capacitance measuring circuit for a touch sensor according to the present invention will now be described in detail with reference to the accompanying drawings.

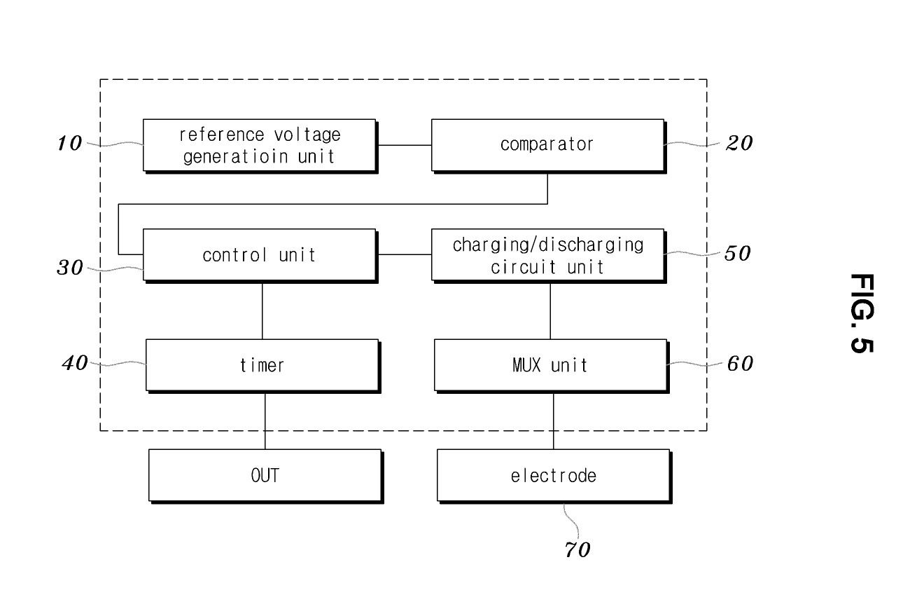

FIG. 5 is a schematic diagram showing a capacitance measuring circuit for a touch sensor according to the present invention.

A capacitance measuring circuit for a touch sensor according to the present invention includes a reference voltage generation unit 10 for generating a first reference voltage and a second reference voltage, a MUX unit 60 for selecting one form among electrodes (PAD) 70 when the number of electrodes touched by a user is plural, a comparator 20 for comparing a voltage generated by the reference voltage generation unit 10 with a voltage input from the electrode, a charging/discharging circuit unit 50 for charging the electrode from the first reference voltage to the second reference voltage or discharging the electrode from the second reference voltage to the first reference voltage, a timer 40 for measuring the charging time and discharging time of the charging/discharging circuit unit and outputting corresponding output signals, and a control unit 30 for receiving the output signals of the comparator 20 and an external control signal and controlling the charging/discharging circuit unit and the timer.

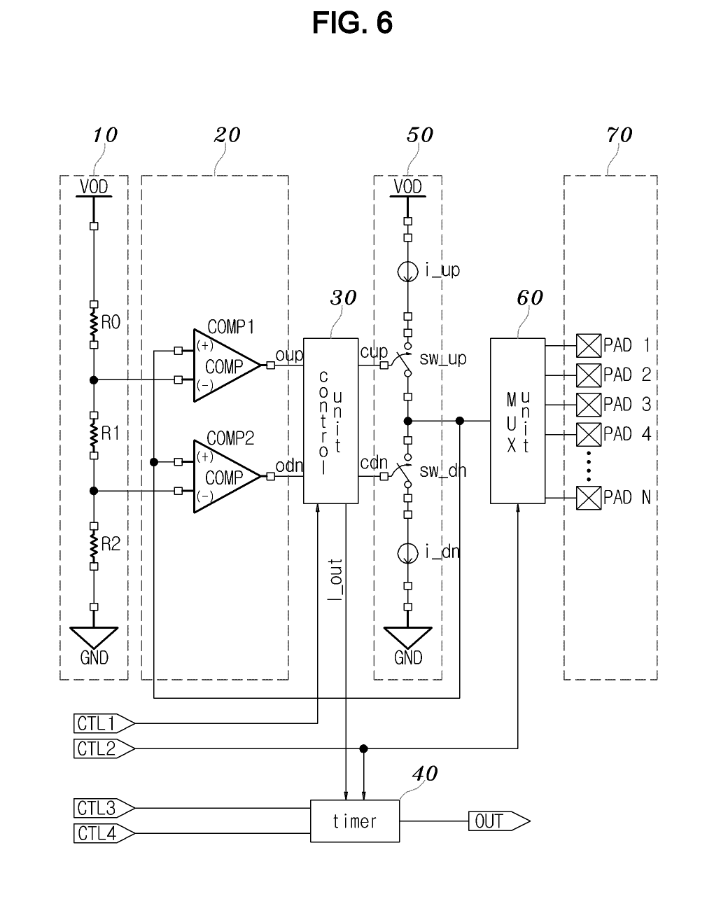

FIG. 6 is a detailed view of the capacitance measuring circuit for a touch sensor according to the present invention.

The reference voltage generation unit 10 is constructed by connecting three resistors, that is, first to third resistors R0, R1 and R2, in series, and generates a first reference voltage Vref_dn and a second reference voltage Vref_up. One terminal of the first resistor R0 is connected to a power source voltage VDD. The second resistor R1 and the third resistor R2 are connected in series. One terminal of the third resistor is connected to a ground GND. The second reference voltage is generated at a node where the first resistor R0 and the second resistor R1 are connected, and the first reference voltage is generated at a node where the second resistor R1 and the third resistor R2 are connected.

The reference voltage generation unit 10 is not limited to the above construction at all, and the first reference voltage and the second reference voltage may be supplied from the outside, or may be obtained from components, other than resistors.

The first reference voltage and the second reference voltage generated by the reference voltage generation unit 10 are compared with an electrode voltage Vpad input from the electrode 70, and then respective output signals odn and oup are output. The reference voltage can be varied by varying the resistance values of the reference voltage generation unit 10.

The comparison of the first reference voltage and the second reference voltage with the electrode voltages Vpad is performed by the comparator 20. The comparator 20 includes a first comparator COMP1 21 and a second comparator COMP2 22. The (−) terminal of the first comparator is connected to the second reference voltage, and the (−) terminal of the second comparator is connected to the first reference voltage. Furthermore, the (+) terminal of each comparator is connected to the electrode voltage Vpad. The functions of the comparator 20 are listed in the following table.

| | Comparator | Condition | Output value |
|---|---|---|---|
| 1 | COMP1 | Vref_up > Vpad | Oup = Low |
| 2 | | Vref_up > Vpad | Oup = High |
| 3 | COMP2 | Vref_dn > Vpad | Odn = Low |
| 4 | | Vref_dn > Vpad | Odn = High |

The control unit 30 controls the charging/discharging circuit unit 50 and the timer 40 based on the output signals odn and oup, output from the comparator 20, and an external control signal CTL1.

The timer 40 receives an external control signal CTL3 and a clock I_out from the control unit 30, measures the charging and discharging time of the charging/discharging circuit unit 50 based on capacitance existing in the electrode 70, and outputs corresponding signals OUT.

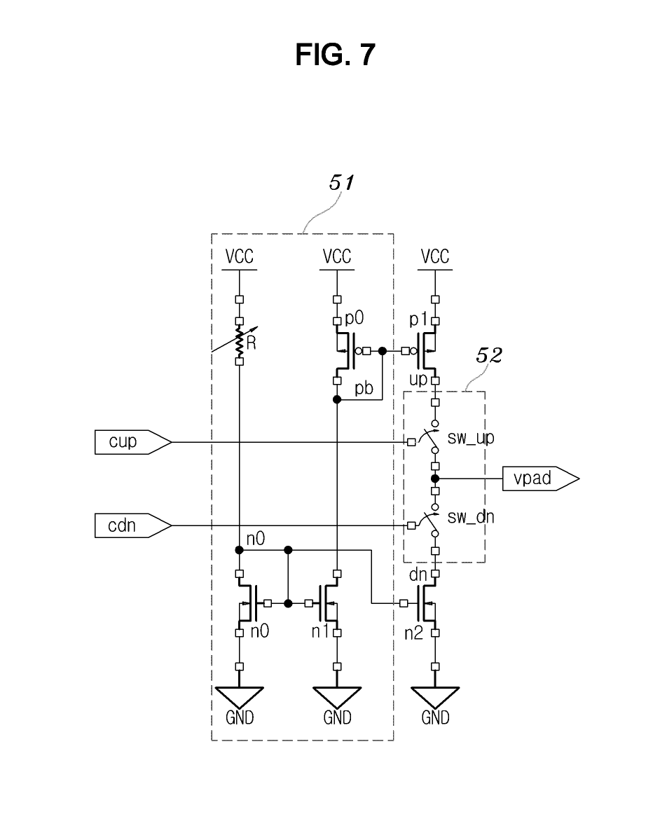

FIG. 7 is a detailed view of the charging/discharging circuit unit according to the present invention.

As shown in FIG. 7, the electrode driver 50 includes a current source 51 for supplying a constant current and a switch unit 52 for selecting charging or discharging. The resistor of the current source 51 is a resistor R for determining the amount of bias current of an NMOS transistor n0. The amount of current flowing between the drain and source GND of the NMOS transistor n0 is determined by the resistance value of the resistor R. An NMOS transistor n1 and a PMOS transistor p0 function to mirror the current of the NMOS transistor n0.

An NMOS transistor n2 and a PMOS transistor p1 are used to perform the charging or discharging of the capacitance of the electrode voltage Vpad, and function to supply an amount of current equal to that of the NMOS transistor n0, which is determined by the resistor R.

The current source 51 will be described in greater detail. One terminal of the resistor R is connected to a power source voltage VCC, and the other terminal thereof is connected to the drain terminal of the NMOS transistor n0. The source terminal of the NMOS transistor n0 is connected to a ground terminal GND, and the gate terminal the NMOS transistor n0 is commonly connected to the gate terminal of the NMOS transistor n1. Furthermore, the drain and gate terminals of the NMOS transistor n0 are commonly connected to the gate terminal of the NMOS transistor n2. The source terminal of the NMOS transistor n2 is connected to a ground terminal GND, and the drain terminal of the NMOS transistor n2 is connected to the switch unit 52, which will be described later.

The drain terminal of the NMOS transistor n1 is connected to the drain terminal of the PMOS transistor p0, and the source terminal of the NMOS transistor n1 is connected to a ground terminal GND. The source terminal of the PMOS transistor p0 is connected to a power source voltage VCC, and the gate terminal of the PMOS transistor p0 is commonly connected to the gate terminal of the PMOS transistor p1. The source terminal of the PMOS transistor p1 is connected to a power source voltage VCC, and the drain terminal of the PMOS transistor p1 is connected to the switch unit 52, which will be described later. Furthermore, the drain and gate terminals of the PMOS transistor p0 are commonly connected to each other.

Meanwhile, variation in the time constant for the value of capacitance, which varies depending on the area of an electrode provided on the PCB of a relevant application product, can be controlled by controlling charging/discharging voltage values in such a way as to change the resistance value of the resistor R of the current source 51.

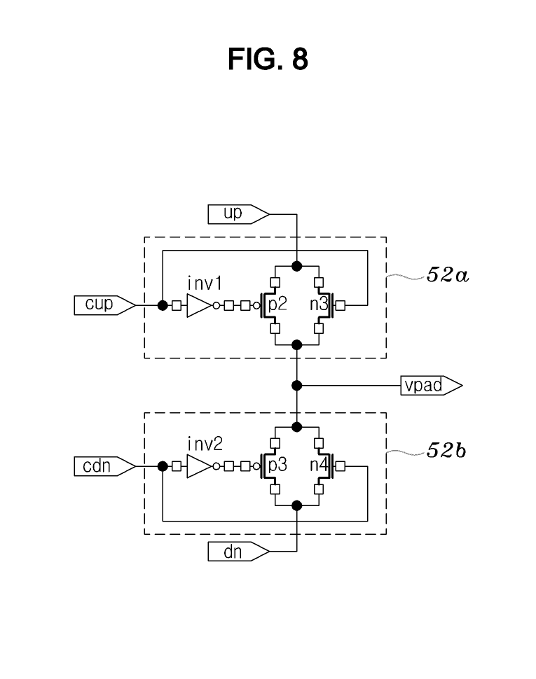

FIG. 8 is a detailed view of the switch unit 52 of the charging/discharging circuit unit according to the present invention. As described above, the switch unit 52 is used to select charging or discharging, and includes analog switches or 2-to-1 analog switches and inverters. The switch unit 52 includes a first switch 52a for selecting charging and a second switch 52b for selecting discharging.

The output signal ‘oup’ of the first comparator COMP1 is connected to the input terminal of a first inverter inv1, and the output signal ‘odn’ of the second comparator COMP2 is connected to the input terminal of the second inverter inv2.

In the case of the first switch 52a, the output terminal of the first inverter inv1 is connected to the gate terminal of a PMOS transistor p2. The source terminal of the PMOS transistor p2 is connected to the drain terminal of an NMOS transistor n3, and the drain terminal of the PMOS transistor p2 is connected to the source terminal of the NMOS transistor n3. The input terminal of the first inverter inv1 is connected to the gate terminal of the NMOS transistor n3.

Furthermore, the source terminal of the PMOS transistor p2 and the drain terminal of the NMOS transistor n3 are connected to the drain terminal of the PMOS transistor p2 of the current source 51.

In the case of the second switch 52b, the output terminal of the second inverter inv2 is connected to the gate terminal of a PMOS transistor p3. The source terminal of the PMOS transistor p3 is connected to the drain terminal of the NMOS transistor n4, and the drain terminal of the PMOS transistor p3 is connected to the source terminal of the NMOS transistor n4. The input terminal of the first inverter inv2 is connected to the gate terminal of the NMOS transistor n4.

Meanwhile, the source terminal of the NMOS transistor n4, which is connected to the drain terminal of the PMOS transistor p3, is connected to the drain terminal of the NMOS transistor n4, which is connected to the source terminal of the PMOS transistor p3. The source terminal of the NMOS transistor n4 is connected to the electrode voltage Vpad.

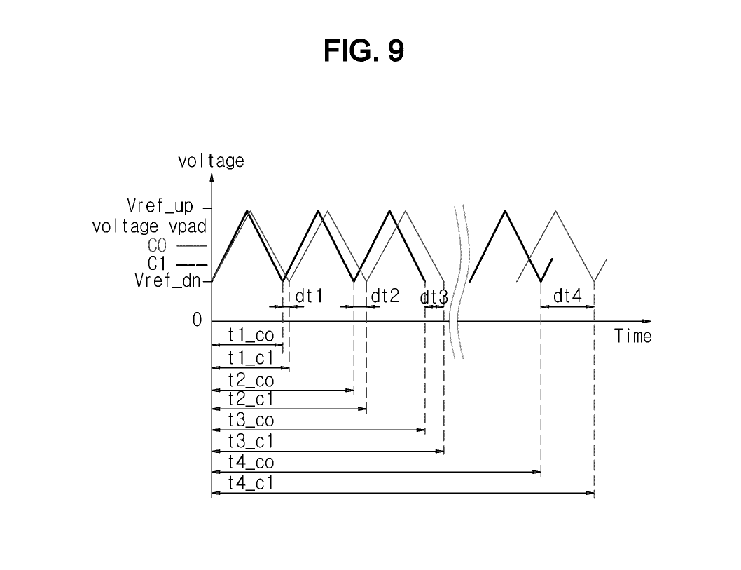

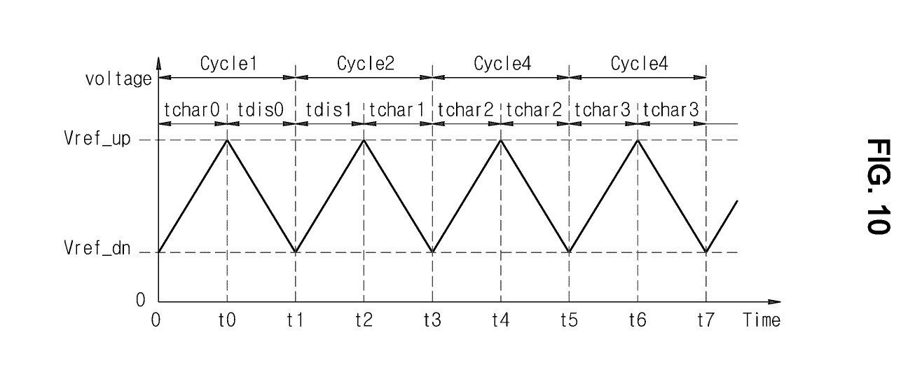

In the case where capacitance increases in the same electrode due to contact with a human body, compared with an existing capacitance, as shown in FIG. 9, the voltage waveform of Vpad is varied from a waveform C0 to a waveform C1. When one cycle is performed, the difference between the time it takes to perform charging and discharging and the existing time is dt0. When two cycles are performed, the difference between the time it takes to perform charging and discharging and the existing time is dt1. When three cycles are performed, the difference between the time it takes to perform charging and discharging and the existing time is dt2. This time difference has the following relationship in proportion to the number of cycles of charging/discharging:

dt2=dt1+dt0

dt1=dt0*2

That is, dtN=dt0*N, and N=number of cycles of charging/discharging.

Accordingly, it can be seen that, as the number of cycles of charging/discharging increases, the time it takes to perform the charging/discharging of increased capacitance, compared to existing capacitance, increases proportionally.

Therefore, the prior art method requires a very fast clock because the time it takes to perform charging or discharging is measured once using a high-speed timer only in the case of charging or discharging in every charging/discharging cycle. In contrast, the present invention can measure a time difference accumulated during N cycles, so that measurement can be performed using a slow clock corresponding to the increased time, compared to the case where the time difference is measured every time. Accordingly, time measurement can be performed more accurately than that in the case where a high-speed clock is used, as in the prior art. As a result, the capacitance formed in the electrode 70 can be measured more accurately.

Furthermore, if the capacity of charging and discharging current used in the present invention is increased, the time it takes to perform charging or discharging is reduced and the number of charging/discharging cycles during specific periods t4_c0 and t4_c1 is increased in proportion to the amount of increased current. However, it can be seen that a timer value based on the difference between capacitances C0 and C1 at the time that the charging/discharging cycle is terminated near the periods t4_c0 and t4_c1 is not significantly different from a value that is obtained before the capacity of charging and discharging current is increased.

Accordingly, it can be seen that, although the charging or discharging current has been increased, a relative difference in the charging/discharging time attributable to the existing capacitances C0 and C1 can be kept relatively uniform in the case where the difference is measured after the number of cycles has been increased in reverse proportion to the shortened cycle time.

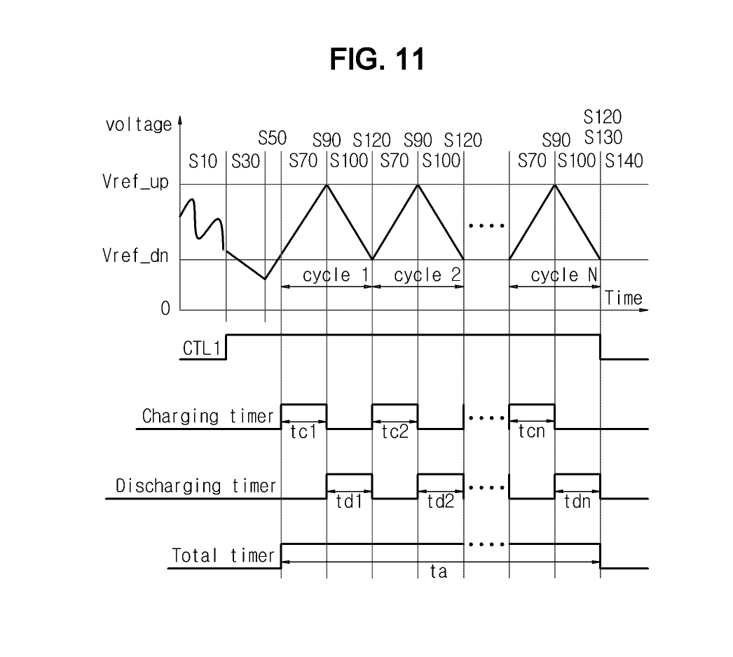

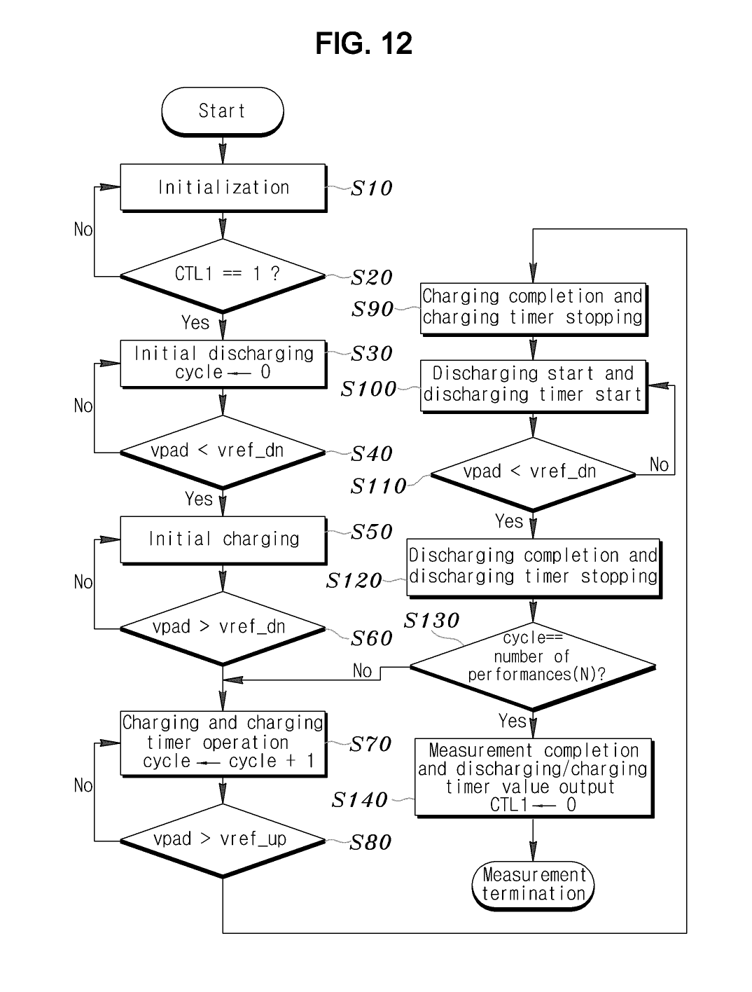

FIG. 12 is a flowchart showing the sequence of the operation of the measurement circuit according to the present invention. The sequence of the operation is described below in detail with reference to FIG. 11. In order to calculate capacitance in the electrode 70, an initial voltage Vpad exists in an open state (high impedance) so as to measure charging time and discharging time at step S10.

Thereafter, when the external control signal CTL1 enters at step S20, the control unit 30 performs discharging so that ‘odn’ becomes 1 and the voltage Vpad is set to a value less than the voltage Vref_dn at step S30.

The voltage Vpad is compared with the first reference voltage Vref_dn at step S40. If, as a result of the comparison, the first reference voltage is higher than the voltage Vpad, discharging is performed until the first reference voltage becomes lower than the voltage Vpad. After discharging is completed, charging is performed until the voltage becomes Vref_dn again at step S50. The voltage Vpad is compared with the first reference voltage Vref_dn at step S60. If, as a result of the comparison, the voltage Vpad is lower than the first reference voltage, charging is performed until the voltage Vpad becomes higher than the first reference voltage.

Thereafter, when the voltage Vpad is equal to the first reference voltage Vref_dn, the timer 40 operates and measures the charging time at step S70. It is determined whether charging to a voltage equal to or higher than the second reference voltage Vref_up has been performed at step S80. If, as a result of the determination, the charging to a voltage equal to or higher than the second reference voltage Vref_up has been performed, the charging is completed and the charging time timer is terminated at step S90.

After the charging to the second reference voltage Vref_up is completed, discharging is performed and, at the same time, the timer operates and measures the discharging time at step S100. When the discharging is completed, the first reference voltage and the voltage Vpad are compared with each other in order to determine whether the discharging to the first reference voltage is completed at step S110. If, as a result of the comparison, the discharging to a voltage equal to or lower than the first reference voltage is completed, the discharging is completed and the measurement of the discharging time is stopped at step S120.

Accordingly, charging/discharging are performed N times at step S130. The charging or discharging time is measured, and charging timer values tc1, tc2, tc3, . . . , and ten corresponding to respective charging times, discharging timer values td1, td2, td3, . . . , and tdn corresponding to respective discharging times, and a total timer value ‘ta’ it takes to perform charging and discharging are output at step S140.

In general, the time ta it takes to perform the charging and discharging of the electrode PAD N times is used as the most important reference value to determine the capacitance of an electrode. However, charging timer values and discharging timer values are additionally output in order to determine whether a human body is actually touched because there is an actual tendency for the charging time and the discharging time to vary from each other due to the external environment. Accordingly, the charging and discharging timer values function to help the logical part of a touch sensor circuit to determine whether an external human body has been touched.

According to the present invention constructed and operated as described above, the parasitic current in a semiconductor and the current having a value significantly higher than noise caused by the external environment can be used to perform the charging and discharging of an electrode. Accordingly, there are advantages in that the time it takes to perform the charging and discharging of the capacitance of an electrode can be measured more stably and accurately, and thus the value of capacitance of the electrode and the variation in the value can also be measured.

Although the present invention has been described in connection with the preferred embodiment for illustrating the principle of the present invention, the present invention is not limited to the construction and operation. Those skilled in the art will appreciate that various modifications, additions and substitutions are possible, without departing from the scope and spirit of the invention as disclosed in the accompanying claims. Therefore, it should be construed that the entire changes, modifications and their equivalents fall within the scope of the present invention.

1. A capacitance measuring circuit for a touch sensor, comprising:
a reference voltage generation unit for generating a first reference voltage and a second reference voltage;
a MUX unit for selecting one from among electrode voltages input through a plurality of electrodes;
a voltage comparator for comparing a voltage generated by the reference voltage generation unit with the electrode voltage input from an electrode;
a charging/discharging circuit unit for performing charging of the input electrode voltage from the first reference voltage to the second reference voltage or performing discharging of the input electrode voltage from the second reference voltage to the first reference voltage;
a timer unit for receiving an external control signal, measuring charging time and discharging time of the charging/discharging circuit unit, measuring entire charging time and entire discharging time, and outputting corresponding output signals; and
a control unit for receiving an output signal of the voltage comparator and the external control signal and controlling the charging/discharging circuit unit and the timer unit.

2. The capacitance measuring circuit as set forth in claim 1, wherein the reference voltage generation unit includes three resistors connected in series, and provides the first reference voltage and the second reference voltage as linear voltages.

3. The capacitance measuring circuit as set forth in claim 1, wherein the voltage comparator comprises:
a second comparator for comparing the first reference voltage provided by the reference voltage generation unit with the electrode voltage generated in the electrode; and
a first comparator for comparing the second reference voltage provided by the reference voltage generation unit with an electrode voltage generated in the electrode.

4. The capacitance measuring circuit as set forth in claim 1, wherein the charging/discharging circuit unit comprises:
a current source for increasing the electrode voltage to the second reference voltage; and
a switch unit for selecting one from among charging and discharging of the electrode voltage.

5. The capacitance measuring circuit as set forth in claim 4, wherein the current source comprises:
a resistor (R) having one terminal connected to a power source voltage (VCC) and a remaining terminal connected to a drain terminal of an NMOS transistor (n0);
the NMOS transistor (n0) having a source terminal connected to a ground terminal and the drain terminal connected to the remaining terminal of the resistor (R);
an NMOS transistor (n1) having a source terminal connected to the ground terminal and a drain terminal connected to a drain terminal of a PMOS transistor (p0);
a PMOS transistor (n2) having a source terminal connected to the ground terminal and a drain terminal connected to the switch unit;
the PMOS transistor (p0) having a source terminal connected to a power source voltage (VCC) and the drain terminal connected to the drain terminal of the NMOS transistor (n1); and
a PMOS transistor (p1) having a source terminal connected to a power source voltage (VCC) and a drain terminal connected to the switch unit;
wherein a gate terminal and drain terminal of the NMOS transistor (n0) and a gate terminal of the NMOS transistor (n1) are commonly connected to a gate terminal of the NMOS transistor (n2); and
wherein the drain terminal and gate terminal of the PMOS transistor (p0) are commonly connected to a gate terminal of the PMOS transistor p1.

6. The capacitance measuring circuit as set forth in claim 4, wherein the switch unit comprises:
a first switch for selecting the charging of the electrode; and
a second switch for selecting the discharging of the electrode.

7. The capacitance measuring circuit as set forth in claim 4 or 6, wherein the switch unit comprises:
a first switch comprising a first inverter having an input terminal connected to an output terminal of the second comparator, and a PMOS transistor (p2) having a source terminal connected to a drain terminal of an NMOS transistor (n3), a drain terminal connected to a source terminal of the NMOS transistor (n3) and a gate terminal connected to an output terminal of the first inverter, wherein the output terminal of the first inverter and a gate terminal of the NMOS transistor (n3) are commonly connected to each other, and the source terminal of the PMOS transistor (p2) and the drain terminal of the NMOS transistor (n3) are connected to the current source; and
a second switch comprising a second inverter having an input terminal connected to an output terminal of the first comparator, and a PMOS transistor (p3) having a source terminal connected to a drain terminal of an NMOS transistor (n4), a drain terminal connected to a source terminal of the NMOS transistor (n4), and a gate terminal connected to an output terminal of the second inverter, wherein the output terminal of the first inverter and a gate terminal of the NMOS transistor (n4) are commonly connected to each other, and the source terminal of the PMOS transistor (p3) and the drain terminal of the NMOS transistor (n4) are connected to the current source.

8. The capacitance measuring circuit as set forth in claim 1, wherein capacitance is measured through an accumulated difference between charging and discharging time for existing capacitance and charging and discharging time for varied capacitance by successively performing a charging and discharging cycle one or more times.

9. A capacitance measuring circuit for a touch sensor, comprising:
a reference voltage generation unit for generating a first reference voltage and a second reference voltage;
a voltage comparator for comparing an electrode voltage input from an electrode with voltage generated by the reference voltage generation unit; and
a charging/discharging circuit unit for performing charging of the input electrode voltage from the first reference voltage to the second reference voltage or performing discharging of the input electrode voltage from the second reference voltage to the first reference voltage;
wherein charging and discharging time and total charging and discharging time consumed through the charging/discharging circuit unit are measured, a charging and discharging cycle is performed two or more times, and capacitance is measured through an accumulated difference between charging and discharging time for existing capacitance and charging and discharging time for varied capacitance using corresponding charging and discharging time and total charging and discharging time.
